(19) United States
(12) Patent Application Publication
(10) Pub. No.: US 2024/0047351 A1
(43) Pub. Date: Feb. 8, 2024

(54) MULTISTEP ETCH FOR DIRECT CHIP ATTACH (DCA) SUBSTRATES, AND ASSOCIATED SYSTEMS AND DEVICES

(71) Applicant: Micron Technology, Inc., Boise, ID (US)

(72) Inventor: Walter L. Moden, Boise, ID (US)

(21) Appl. No.: 17/882,441

(22) Filed: Aug. 5, 2022

(51) Int. Cl. H01L 23/528; H01L 21/56; H01L 21/308; H01L 23/532; H01L 23/495; H01L 27/105

(52) U.S. Cl. CPC H01L 23/528; H01L 21/563; H01L 21/308; H01L 23/53204; H01L 23/49503; H01L 27/105

(57) ABSTRACT

Semiconductor devices, such as memory devices, and associated systems and methods, are disclosed herein. A representative semiconductor device comprises a substrate including a plurality of conductive contacts and a mask material having a surface. The mask material includes (a) a first recess formed in the surface having a first depth and (b) a second recess formed in the surface having a second depth greater than the first depth. An exposed portion of each of the conductive contacts is exposed from the mask material in the second recess. The semiconductor device further comprises a semiconductor die including a lower surface having bond pads, and the lower surface is positioned in the first recess. The semiconductor device further comprises a plurality of conductive features electrically coupling individual ones of the bond pads to corresponding ones of the exposed portions of the conductive contacts.

### TECHNICAL FIELD

The present disclosure generally relates to semiconductor devices, such as memory devices, including a direct chip attach (DCA) substrate having multiple etched recesses in a solder mask layer to expose conductive contacts of the substrate.

### BACKGROUND

Memory packages or modules typically include multiple memory devices mounted on a substrate. Memory devices are widely used to store information related to various electronic devices such as computers, wireless communication devices, cameras, digital displays, and the like. Information is stored by programing different states of a memory cell. Various types of memory devices exist, including magnetic hard disks, random access memory (RAM), read only memory (ROM), dynamic RAM (DRAM), synchronous dynamic RAM (SDRAM), and others. Improving memory packages, generally, may include increasing memory cell density, increasing read/write speeds or otherwise reducing operational latency, increasing reliability, increasing data retention, reducing power consumption, reducing manufacturing costs, and reducing the size or footprint of the memory packages and/or components of the memory devices, among other metrics.

### BRIEF DESCRIPTION OF THE DRAWINGS

Many aspects of the present technology can be better understood with reference to the following drawings. The components in the drawings are not necessarily to scale. Instead, emphasis is placed on illustrating clearly the principles of the present technology.

FIG. 1A is a side cross-sectional view of a semiconductor device in accordance with embodiments of the present technology.

FIG. 1B is an enlarged view of a portion of the semiconductor device shown in FIG. 1A in accordance with embodiments of the present technology.

FIGS. 2A-2F are side cross-sectional views illustrating various stages in a method of manufacturing the semiconductor device of FIGS. 1A and 1B in accordance with embodiments of the present technology.

FIG. 3 is an enlarged, partially-schematic isometric view of a portion of a semiconductor device in accordance with additional embodiments of the present technology.

### DETAILED DESCRIPTION

Embodiments of the present technology are directed to semiconductor devices, such as memory devices, and associated systems and methods. In several of the embodiments described below, a representative semiconductor device includes a substrate, a semiconductor die, and a plurality of conductive features electrically coupling the semiconductor die to the substrate. The substrate can include (i) a base having an upper surface, (ii) a plurality of conductive contacts extending from the upper surface of the base, and (iii) a mask material over the upper surface of the base and having a stepped upper surface. The stepped upper surface of the mask material can include (i) an upper surface portion extending to a first height above the upper surface of the base, (ii) a mid surface portion extending to a second height above the upper surface of the base less than the first height, and (iii) a lower surface portion extending to a third height above the upper surface of the base less than the second height. The upper portion of each of the conductive contacts can extend above the lower surface portion of the mask material such that the conductive contacts are exposed from the mask material. The semiconductor die can include a lower surface having bond pads, and the lower surface can be positioned over the mid surface portion and the lower surface portion of the mask material, and beneath the upper surface portion of the mask material. In some embodiments, the mid surface portion defines a recess in which the lower surface of the semiconductor die is positioned. The plurality of conductive features can electrically couple individual ones of the bond pads to corresponding ones of the upper portions of the conductive contacts.

In some aspects of the present technology, positioning the semiconductor die partially in a recess formed by the mid surface portion of the mask material can position the bond pads of the semiconductor die close to the conductive contacts of the substrate—thereby reducing a required height of the conductive features. Reducing the height of the conductive features can improve the strength and integrity and/or reduce the manufacturing costs of the semiconductor device. For example, shortening the conductive features can reduce the likelihood of the conductive features warping or breaking due to thermal stresses within the semiconductor device.

In some embodiments, the conductive contacts are first conductive contacts, and the substrate can further include a plurality of second conductive contacts extending from the upper surface of the base beneath the mid surface portion and to a fourth height less than the second height such that mask material covers an upper portion of each of the second conductive contacts. The semiconductor device can further include an underfill material between the mask material and the semiconductor die. In some aspects of the present technology, covering the second conductive contacts with the mask material can help reduce the likelihood of electromigration issues and/or improve the adhesion of the underfill material within the semiconductor device. For example, not exposing the second conductive contacts from the mask material can reduce the amount of exposed conductive material within the semiconductor device. Moreover, the underfill material can adhere better to the mask material than to the conductive contacts of the substrate.

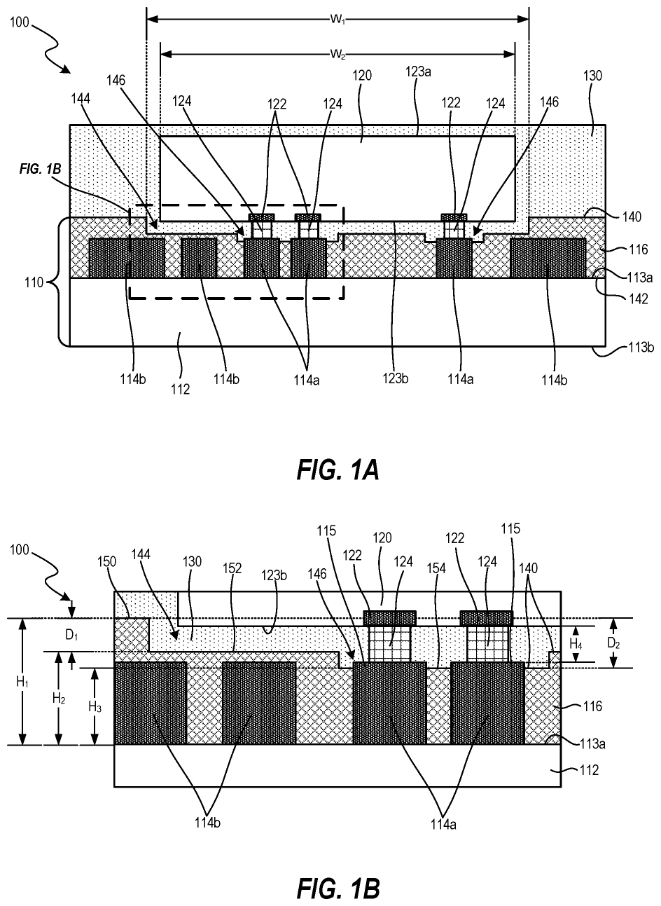

Numerous specific details are discussed to provide a thorough and enabling description of embodiments of the present technology. A person skilled in the art, however, will understand that the technology may have additional embodiments and that the technology may be practiced without several of the details of the embodiments described below with reference to FIGS. 1A-3. In other instances, well-known structures or operations often associated with semiconductor devices, memory devices, etc., are not shown, or are not described in detail, to avoid obscuring other aspects of the technology. In general, it should be understood that various other devices and systems in addition to those specific embodiments disclosed herein may be within the scope of the present technology.

As used herein, the terms “vertical,” “lateral,” “upper,” “lower,” “above,” and “below” can refer to relative directions or positions of features in the semiconductor devices in view of the orientation shown in the Figures. For example, “upper” or “uppermost” can refer to a feature positioned closer to the top of a page than another feature. These terms, however, should be construed broadly to include semiconductor devices having other orientations, such as inverted or inclined orientations where top/bottom, over/under, above/below, up/down, and left/right can be interchanged depending on the orientation.

FIG. 1A is a side cross-sectional view of a semiconductor device 100 (e.g., a memory device) in accordance with embodiments of the present technology. FIG. 1B is an enlarged view of a portion of the semiconductor device 100 in accordance with embodiments of the present technology. Referring to FIG. 1A, the semiconductor device 100 includes a substrate 110, a semiconductor die 120 positioned over the substrate 110 and electrically coupled to the substrate 110, and a mold or underfill material 130 (e.g., a molded underfill material) over the substrate 110 and at least partially between the semiconductor die 120 and the substrate 110.

The substrate 110 can be a printed circuit board (PCB), an interposer, a dielectric spacer, a semiconductor die (e.g., a logic die), and/or or the like. In some embodiments, the substrate 110 is a direct chip attach (DCA) substrate. In the illustrated embodiment, the substrate 110 includes (i) a base 112 having an upper surface 113a (e.g., a first side or surface) and a lower surface 113b (e.g., a second side or surface), (ii) a plurality of conductive contacts 114 (including individually identified first contacts 114a and second contacts 114b) positioned on the upper surface 113a of the base 112 and/or electrically coupled to the base 112, and (iii) a mask material 116 (e.g., a solder mask) positioned on the upper surface 113a of the base 112 and at least partially surrounding the contacts 114.

The contacts 114 can be bond fingers, bond pads, and/or the like and can be formed of copper or other suitably conductive materials (e.g., metals). The base 112 can be a silicone substrate or the like and, in some embodiments, the lower surface 113b of the base 112 can be connected to electrical connectors (e.g., solder balls; not shown) configured to electrically couple the semiconductor device 100 to external circuitry (not shown). The base 112 can further include electrical lines, traces, and/or the like extending therethrough and/or thereacross that electrically connect (i) the contacts 114 to the electrical connectors and external circuitry and/or (ii) two or more of the contacts 114 to one another. The mask material 116 can be formed of a polymer or other material and can inhibit solder bridging and/or other electromigration between the contacts 114.

The semiconductor die 120 can have integrated circuits or components, data storage elements, processing components, and/or other features manufactured on semiconductor substrates. For example, the semiconductor die 120 can include integrated memory circuitry and/or logic circuitry, which can include various types of semiconductor components and functional features, such as dynamic random-access memory (DRAM), static random-access memory (SRAM), flash memory, other forms of integrated circuit memory, processing circuits, imaging components, and/or other semiconductor features. In some embodiments, the semiconductor die 120 is a memory die including integrated memory circuitry.

In the illustrated embodiment, the semiconductor die 120 includes an upper surface 123a (e.g., a first side or surface), a lower surface 123b (e.g., a second side or surface) opposite the upper surface 123a, and a plurality of bond pads 122 exposed at the lower surface 123b. The bond pads 122 of the semiconductor die 120 are electrically coupled to corresponding ones of the first contacts 114a of the substrate 110 via conductive features 124 such that, for example, the semiconductor die 120 is flip-chip bonded (e.g., directly attached) to the substate 110. The conductive features 124 can have various suitable structures, such as pillars, columns, studs, bumps, and/or the like, and can be made from copper, nickel, solder (e.g., SnAg-based solder), conductor-filled epoxy, and/or other electrically conductive materials. In some embodiments, the conductive features 124 are copper pillars formed from, for example, a thermocompression bonding process (e.g., copper-copper (Cu—Cu) bonding).

In the illustrated embodiment, the mask material 116 includes an upper surface 140 (e.g., a first side or surface) facing away from the base 112 and a lower surface 142 (e.g., a second side or surface) opposite the upper surface 140 and facing and abutting the base 112. Referring to FIGS. 1A and 1B together, the upper surface 140 of the mask material 116 can be etched to define one or more first etches or recesses 144 and one or more second etches or recesses 146. The first recess 144 can be formed in the mask material 116 at least partially below the semiconductor die 120, and the second recesses 146 can be formed in the mask material 116 at least partially around the first contacts 114a such that the first contacts 114a can be electrically coupled to corresponding ones of the bond pads 122 of the semiconductor die 120. In some embodiments, the first recess 144 is formed entirely below (e.g., below an entire footprint of) the semiconductor die 120. That is, the first recess 144 can have a first width W₁ greater than a width W₂ of the semiconductor die 120 such that the semiconductor die 120 can be positioned at least partially in the first recess 144.

Referring to FIG. 1B, the first and second recesses 144, 146 give the upper surface 140 a stepped shape or pattern including (i) an upper surface portion 150 (e.g., a first surface portion) extending to a first elevation or height H₁ above the upper surface 113a of the base 112, (ii) a mid surface portion (e.g., a second surface portion) extending to a second elevation or height H₂ less than the first height H₁ above the upper surface 113a of the base 112, and (iii) a lower surface portion (e.g., a third surface portion) extending to a third elevation or height H₃ above the upper surface 113a of the base 112 less than the second height H₂. Accordingly, the first recess 144 can have a depth D₁ (e.g., a distance between the upper surface portion 150 and the mid surface portion 152) and the second recesses 146 can have a depth D₂ (e.g., a distance between the upper surface portion 150 and the lower surface portion 154).

The depth D₁ can be selected such that the second contacts 114b are not exposed from the mask material 116 in the first recess 144 and therefore electrically inaccessible. The depth D₂ can be selected such that at least a portion (e.g., an upper portion 115) of the first contacts 114a are exposed from the mask material 116 in the second recesses 146 and therefore electrically accessible. The depth D₁ can be between about 40% to 95% of the depth D₂ and/or between about 40% to 95% of a distance between the upper surface portion 150 and the upper portions 115 of the first contacts 114a. In some embodiments, the depth D₁ is between about 5-20 μm. The depth D₂ can be selected to only expose the upper portions 115 of the first contacts 114a. In some embodiments, the depth D₂ is between about 5-25 μm.

Referring to FIGS. 1A and 1B together, the lower surface 123b of the semiconductor die 120 can be positioned at least partially within the first recess 144 such that, for example, the lower surface 123b is positioned at a height below the height H₁ of the upper surface portion 150. The conductive features 124 can extend from the bond pads 122 at least partially through the first recess 144 and a corresponding one of the second recesses 146 to the corresponding ones of the first contacts 114a exposed in the second recesses 146.

In the illustrated embodiment, the underfill material 130 is positioned in the first and second recesses 144,146 between the semiconductor die 120 and the mask material 116 to surround the conductive features 124. In some embodiments, the underfill material 130 can further be positioned on the upper surface portion 150 and/or around the semiconductor die 120 to encase the semiconductor die 120. For example, the underfill material 130 can be a molded underfill material (MUF). In other embodiments, a mold or other material separate from the underfill material 130 can be used to encase and protect the semiconductor die 120.

In a first aspect of the present technology, positioning the semiconductor die 120 at least partially in the first recess 144 (e.g., with the lower surface 123b of the semiconductor die 120 below the upper surface portion 150 of the mask material 116) can position the bond pads 122 close to the corresponding ones of the first contacts 144a—thereby reducing a required height of the conductive features 124. For example, the conductive features 124 can have a height H₄ (FIG. 1B) of between about 5-80 μm, between about 5-20 μm, or between about 10-80 μm. The height H₄ can be selected to allow the underfill material 130 to flow between the semiconductor die 120 and the substrate 110 and, accordingly, can be selected depending on the characteristics of the underfill material 130. In contrast, if the first recess 144 were omitted, the lower surface 123b of the semiconductor die 120 would need to be positioned at or above the upper surface portion 150—thereby increasing the required height H₄ of the conductive features 124. Reducing the height H₄ of the conductive features 124 (e.g., shortening the conductive features 124) can reduce the overall profile of the semiconductor device 100, improve the strength/integrity of the semiconductor device 100, and/or reduce the manufacturing costs of the semiconductor device 100. For example, shortening the conductive features 124 can reduce the likelihood of the conductive features 124 warping or breaking due to thermal stresses within the semiconductor device 100.

In a second aspect of the present technology, forming the first recess 144 such that second contacts 114b are not exposed from the mask material 116 can help reduce the likelihood of electromigration issues and/or improve the adhesion of the underfill material 130 within the semiconductor device 100. For example, not exposing the second contacts 114b reduces the amount of exposed conductive material within the semiconductor device 100. Moreover, the underfill material 130 is expected to adhere better to the mask material 116 than to the contacts 114 or the base 112 of the substrate 110. In contrast, for example, the second contacts 114b would be exposed from the mask material 116 if the mask material 116 was etched in a single etching step to the height H₃ along the entirety of the first recess 144.

In a third aspect of the present technology, the mask material 116 forms a constant layer (e.g., at least to the height H₃ shown in FIG. 1B) over the base 112 of the substrate 110 such that the base 112 is not exposed from the mask material. Likewise, the first depth D₁ can be selected to be shallow enough to sufficiently reduce the height H₄ of the conductive features 124, and the second depth D₂ can be selected to be shallow enough to only expose the upper portions 115 of the first contacts 114a within the second recesses 146. Accordingly, the relatively shallow depths D₁ and D₂ can reduce the surface profile (e.g., topology) of the upper surface 140 of the mask material 116, which can improve the filling of the underfill material 130 in the first and second recesses 144, 146 and reduce potential void spaces. In contrast, for example, etching the mask material 116 entirely to the base 112 (e.g., thereby exposing the upper surface 113a of the base 112 between the contacts 114) would provide an increased surface profile that is difficult to fully fill with the underfill material 130.

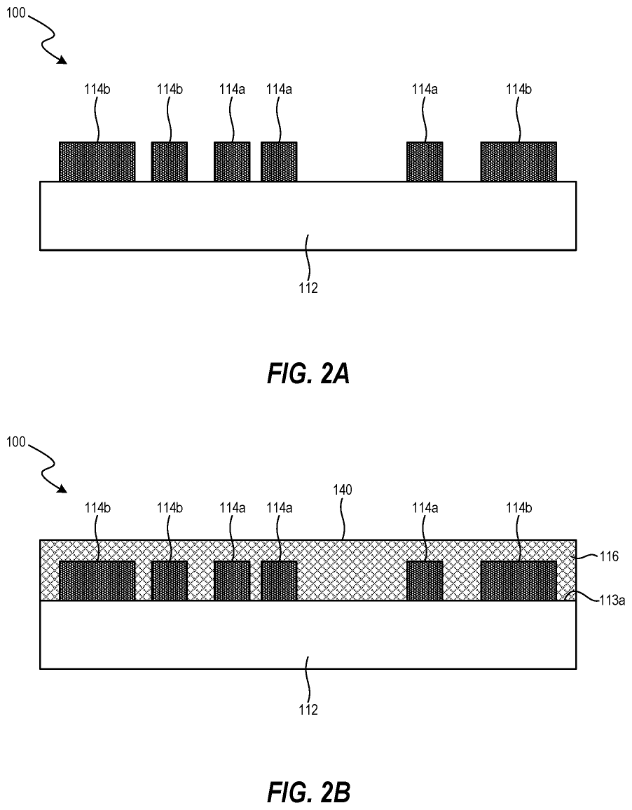

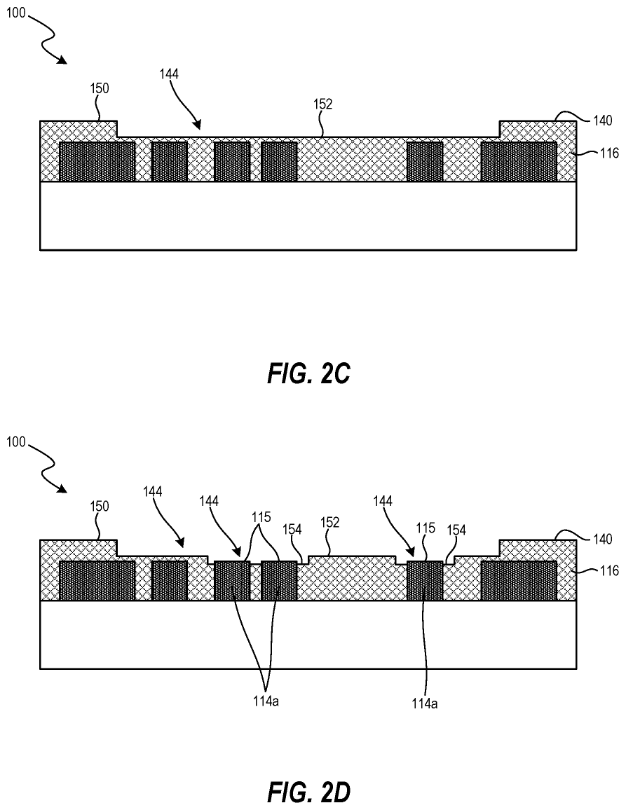

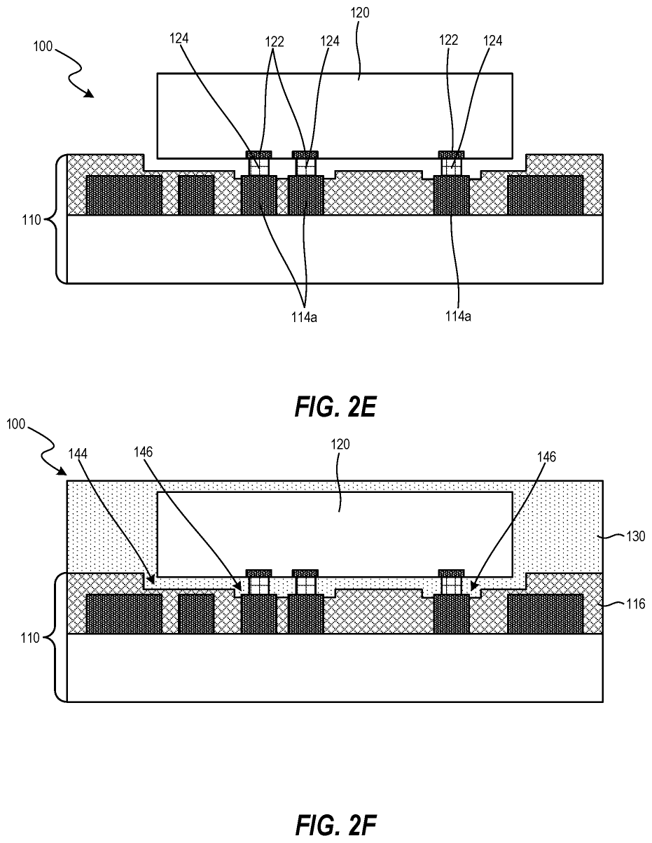

FIGS. 2A-2F are side cross-sectional views illustrating various stages in a method of manufacturing the semiconductor device 100 of FIGS. 1A and 1B in accordance with embodiments of the present technology. Generally, the semiconductor device 100 can be manufactured, for example, as a discrete device or as part of a larger wafer or panel. In wafer-level or panel-level manufacturing, a larger structure is formed before being singulated to form a plurality of individual structures. For ease of explanation and understanding, FIGS. 2A-2F illustrate the fabrication of a single semiconductor device 100. However, the fabrication of the semiconductor device 100 can be scaled to the wafer and/or panel level—that is, to include many more components so as to be capable of being singulated into two or more semiconductor devices 100—while including similar features and using similar processes as described herein.

Referring to FIG. 2A, fabrication of the semiconductor device 100 begins with fabrication of the substrate 110—including the formation of the contacts 114 on the base 112. The contacts 114 can be formed using suitable semiconductor wafer fabrication processes such as sputtering, physical vapor deposition (PVD), electroplating, lithography, etc.

FIG. 2B illustrates the semiconductor device 100 after deposition of the mask material 116 over the contacts 114 and the upper surface 113a of the base 112. The mask material 116 can be deposited using suitable semiconductor wafer fabrication processes such as film deposition, chemical vapor deposition, physical vapor deposition, atomic layer deposition, spin coating, and/or other suitable techniques. After its initial deposition, the upper surface 140 of the mask material 116 can be generally planar and completely cover the contacts 114.

FIG. 2C illustrates the semiconductor device 100 after etching the first recess 144 into the upper surface 140 of the mask material 116 to form the upper surface portion 150 and the mid surface portion 152, and FIG. 2D illustrates the semiconductor device 100 after etching the second recesses 146 into the upper surface 140 of the mask material 116 to further form the lower surface portion 154 and to expose the upper portions of the first contacts 114a. Referring to FIGS. 2C and 2D together, the mask material 116 can be etched using suitable semiconductor wafer fabrication processes such as an anisotropic etching process, a dry etching process, a plasma etching process, wet etching process, etc. In some embodiments, because the depths D₁ and D₂ (FIG. 1B) of the first and second recesses 144, 146, respectively, can be relatively shallow, the etching process can precisely form the first and second recesses 144, 146.

Referring to FIG. 2E, fabrication of the semiconductor device 100 continues with electrically coupling the semiconductor die 120 to the substrate 110. Specifically, the semiconductor die 120 can be “flip-chip bonded” or “direct chip attached” to the substrate 110 such that the bond pads 122 of the semiconductor die 120 are electrically coupled to corresponding ones of the first contacts 114a of the substrate 110 via the conductive features 124. In some embodiments, the bond pads 122 are coupled to the first contacts 114a using solder or a solder paste. In other embodiments, another process such as thermo-compression bonding (e.g., copper-copper (Cu—Cu) bonding) can be used to form conductive Cu—Cu joints between the bond pads 122 and the first contacts 114a.

FIG. 2F illustrates the semiconductor device 100 after depositing the underfill material 130 over the substrate 110 in the first and second recesses 144, 146 of the mask material 116, and to surround (e.g., encapsulate) the semiconductor die 120. In some embodiments, the underfill material 130 is a molded underfill (MUF), such as a mold resin, that can be flowed or otherwise applied to simultaneously (i) fill the space (e.g., gap) between the semiconductor die 120 and the substrate 110 and (ii) over mold/encapsulate the semiconductor die 120. In other embodiments, in a first step, an underfill material can be deposited in the first and second recesses 144, 146 to fill the gap between the semiconductor die 120 and the substrate 110 and, in a second step, a mold material can be deposited over/around the semiconductor die 120.

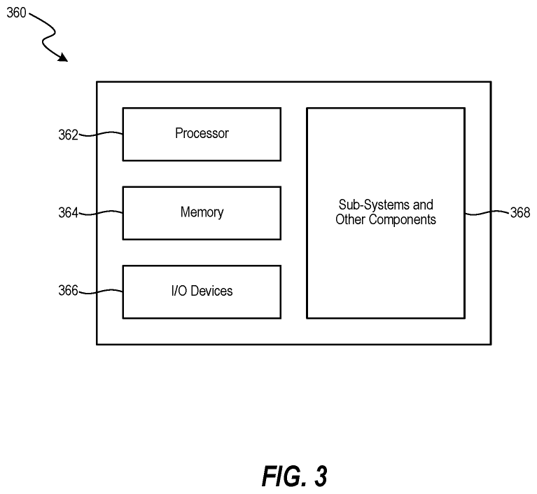

The semiconductor devices (e.g., the semiconductor device 100) described in detail above with reference to FIGS. 1A-2F and/or packages incorporating the memory device can be incorporated into any of a myriad of larger and/or more complex systems, a representative example of which is system 360 shown schematically in FIG. 3. The system 360 can include a processor 362, a memory 364 (e.g., SRAM, DRAM, NAND, flash, and/or other memory devices), input/output devices 366, and/or other subsystems or components 368. The memory devices and/or packages described above with reference to FIGS. 1A-2F can be included in any of the elements shown in FIG. 3. The resulting system 360 can be configured to perform any of a wide variety of suitable computing, processing, storage, sensing, imaging, and/or other functions. Accordingly, representative examples of the system 360 include, without limitation, computers and/or other data processors, such as desktop computers, laptop computers, Internet appliances, hand-held devices (e.g., palm-top computers, wearable computers, cellular or mobile phones, personal digital assistants, music players, and so on), tablets, multi-processor systems, processor-based or programmable consumer electronics, network computers, and minicomputers. Additional representative examples of the system 360 include lights, cameras, vehicles, etc. With regard to these and other example, the system 360 can be housed in a single unit or distributed over multiple interconnected units, for example, through a communication network. The components of the system 360 can accordingly include local and/or remote memory storage devices and any of a wide variety of suitable computer-readable media.

The following examples are illustrative of several embodiments of the present technology:

1. A semiconductor device, comprising:
a substrate including a plurality of conductive contacts and a mask material having a surface, wherein the mask material includes (a) a first recess formed in the surface having a first depth and (b) a second recess formed in the surface having a second depth greater than the first depth, and wherein an exposed portion of each of the conductive contacts is exposed from the mask material in the second recess;
a semiconductor die including a lower surface having bond pads, wherein the lower surface is positioned in the first recess; and
a plurality of conductive features electrically coupling individual ones of the bond pads to corresponding ones of the exposed portions of the conductive contacts.

2. The semiconductor device of example 1 wherein the substrate further includes a base, wherein the conductive contacts extend from the base, and wherein the mask material substantially covers the base around the conductive contacts.

3. The semiconductor device of example 1 or example 2 wherein the mask material is a solder mask.

4. The semiconductor device of any one of examples 1-4 wherein the conductive features are copper pillars.

5. The semiconductor device of any one of examples 1-4 wherein the semiconductor die is a memory die.

6. The semiconductor device of any one of examples 1-5 wherein the first recess has a depth of between 5-20 μm.

7. The semiconductor device of any one of examples 1-6 wherein the second recess has a depth of between 5-25 μm.

8. The semiconductor device of any one of examples 1-7 wherein the conductive features have a height of between 10-80 μm.

9. The semiconductor device of any one of examples 1-8, further comprising an underfill material in the first and second recesses.

10. The semiconductor device of any one of examples 1-9, further comprising a molded underfill material in the first and second recesses and encapsulating the semiconductor die.

11. The semiconductor device of any one of examples 1-10 wherein the conductive contacts are first conductive contacts, wherein the substrate further includes a plurality of second conductive contacts, and wherein the mask material covers the second conductive contacts.

12. A substrate, comprising:
a base having an upper surface;
a plurality of conductive contacts extending from the upper surface of the base; and
a mask material over the upper surface of the base and having a stepped upper surface including (a) an upper surface portion extending to a first height above the upper surface of the base, (b) a mid surface portion extending to a second height above the upper surface of the base less than the first height, and (c) a lower surface portion extending to a third height above the upper surface of the base less than the second height, wherein an upper portion of each of the conductive contacts extends above the lower surface portion and is exposed from the mask material.

13. The substrate of example 12 wherein the conductive contacts are first conductive contacts, and wherein the substrate further comprises a plurality of second conductive contacts extending from the upper surface of the base beneath the mid surface portion and to a fourth height less than the second height such that mask material covers an upper portion of each of the second conductive contacts.

14. The substrate of example 12 or example 13 wherein the mask material substantially covers the upper surface of the base around the conductive contacts.

15. The substrate of any one of examples 12-14 wherein the mask material is a solder mask.

16. A semiconductor device, comprising:
a substrate including—
   a base having an upper surface;
   a plurality of conductive contacts extending from the upper surface of the base; and
   a mask material over the upper surface of the base and having a stepped upper surface including (a) an upper surface portion extending to a first height above the upper surface of the base, (b) a mid surface portion extending to a second height above the upper surface of the base less than the first height, and (c) a lower surface portion extending to a third height above the upper surface of the base less than the second height, wherein an upper portion of each of the conductive contacts extends above the lower surface portion and is exposed from the mask material;
a semiconductor die including a lower surface having bond pads, wherein the lower surface is positioned over the mid surface portion and the lower surface portion and beneath the upper surface portion; and
a plurality of conductive features electrically coupling individual ones of the bond pads to corresponding ones of the upper portions of the conductive contacts.

17. The semiconductor device of example 16 wherein the mid surface portion defines a recess, and wherein the semiconductor die is positioned at least partially in the recess.

18. The semiconductor device of example 16 or example 17 wherein the conductive contacts are first conductive contacts, and wherein the substrate further includes a plurality of second conductive contacts extending from the upper surface of the base beneath the mid surface portion and to a fourth height less than the second height such that mask material covers an upper portion of each of the second conductive contacts.

19. The semiconductor device of any one of examples 16-18 wherein the mask material substantially covers the upper surface of the base around the conductive contacts.

20. The semiconductor device of any one of examples 16-19 wherein the conductive features have a height of between 5-20 μm.

The above detailed description of embodiments of the present technology are not intended to be exhaustive or to limit the technology to the precise forms disclosed above. Although specific embodiments of, and examples for, the technology are described above for illustrative purposes, various equivalent modifications are possible within the scope of the technology as those skilled in the relevant art will recognize. For example, although steps are presented in a given order, other embodiments may perform steps in a different order. The various embodiments described herein may also be combined to provide further embodiments.

From the foregoing, it will be appreciated that specific embodiments of the technology have been described herein for purposes of illustration, but well-known structures and functions have not been shown or described in detail to avoid unnecessarily obscuring the description of the embodiments of the technology. Where the context permits, singular or plural terms may also include the plural or singular term, respectively.

As used herein, the phrase “and/or” as in “A and/or B” refers to A alone, B alone, and A and B. To the extent any materials incorporated herein by reference conflict with the present disclosure, the present disclosure controls. Additionally, the term “comprising” is used throughout to mean including at least the recited feature(s) such that any greater number of the same feature and/or additional types of other features are not precluded. It will also be appreciated that specific embodiments have been described herein for purposes of illustration, but that various modifications may be made without deviating from the technology. Further, while advantages associated with some embodiments of the technology have been described in the context of those embodiments, other embodiments may also exhibit such advantages, and not all embodiments need necessarily exhibit such advantages to fall within the scope of the technology. Accordingly, the disclosure and associated technology can encompass other embodiments not expressly shown or described herein.

I/We claim:

1. A semiconductor device, comprising:
a substrate including a plurality of conductive contacts and a mask material having a surface, wherein the mask material includes (a) a first recess formed in the surface having a first depth and (b) a second recess formed in the surface having a second depth greater than the first depth, and wherein an exposed portion of each of the conductive contacts is exposed from the mask material in the second recess;
a semiconductor die including a lower surface having bond pads, wherein the lower surface is positioned in the first recess; and
a plurality of conductive features electrically coupling individual ones of the bond pads to corresponding ones of the exposed portions of the conductive contacts.

2. The semiconductor device of claim 1 wherein the substrate further includes a base, wherein the conductive contacts extend from the base, and wherein the mask material substantially covers the base around the conductive contacts.

3. The semiconductor device of claim 1 wherein the mask material is a solder mask.

4. The semiconductor device of claim 1 wherein the conductive features are copper pillars.

5. The semiconductor device of claim 1 wherein the semiconductor die is a memory die.

6. The semiconductor device of claim 1 wherein the first recess has a depth of between 5-20 μm.

7. The semiconductor device of claim 1 wherein the second recess has a depth of between 5-25 μm.

8. The semiconductor device of claim 1 wherein the conductive features have a height of between 10-80 μm.

9. The semiconductor device of claim 1, further comprising an underfill material in the first and second recesses.

10. The semiconductor device of claim 1, further comprising a molded underfill material in the first and second recesses and encapsulating the semiconductor die.

11. The semiconductor device of claim 1 wherein the conductive contacts are first conductive contacts, wherein the substrate further includes a plurality of second conductive contacts, and wherein the mask material covers the second conductive contacts.

12. A substrate, comprising:
a base having an upper surface;
a plurality of conductive contacts extending from the upper surface of the base; and
a mask material over the upper surface of the base and having a stepped upper surface including (a) an upper surface portion extending to a first height above the upper surface of the base, (b) a mid surface portion extending to a second height above the upper surface of the base less than the first height, and (c) a lower surface portion extending to a third height above the upper surface of the base less than the second height, wherein an upper portion of each of the conductive contacts extends above the lower surface portion and is exposed from the mask material.

13. The substrate of claim 12 wherein the conductive contacts are first conductive contacts, and wherein the substrate further comprises a plurality of second conductive contacts extending from the upper surface of the base beneath the mid surface portion and to a fourth height less than the second height such that mask material covers an upper portion of each of the second conductive contacts.

14. The substrate of claim 12 wherein the mask material substantially covers the upper surface of the base around the conductive contacts.

15. The substrate of claim 12 wherein the mask material is a solder mask.

16. A semiconductor device, comprising:
a substrate including—
a base having an upper surface;
a plurality of conductive contacts extending from the upper surface of the base; and
a mask material over the upper surface of the base and having a stepped upper surface including (a) an upper surface portion extending to a first height above the upper surface of the base, (b) a mid surface portion extending to a second height above the upper surface of the base less than the first height, and (c) a lower surface portion extending to a third height above the upper surface of the base less than the second height, wherein an upper portion of each of the conductive contacts extends above the lower surface portion and is exposed from the mask material;
a semiconductor die including a lower surface having bond pads, wherein the lower surface is positioned over the mid surface portion and the lower surface portion and beneath the upper surface portion; and
a plurality of conductive features electrically coupling individual ones of the bond pads to corresponding ones of the upper portions of the conductive contacts.

17. The semiconductor device of claim 16 wherein the mid surface portion defines a recess, and wherein the semiconductor die is positioned at least partially in the recess.

18. The semiconductor device of claim 16 wherein the conductive contacts are first conductive contacts, and wherein the substrate further includes a plurality of second conductive contacts extending from the upper surface of the base beneath the mid surface portion and to a fourth height less than the second height such that mask material covers an upper portion of each of the second conductive contacts.

19. The semiconductor device of claim 16 wherein the mask material substantially covers the upper surface of the base around the conductive contacts.

20. The semiconductor device of claim 16 wherein the conductive features have a height of between 5-20 μm.
